(19) United States
(12) Patent Application Publication
(10) Pub. No.: US 2025/0356095 A1
(43) Pub. Date: Nov. 20, 2025

(54) INEQUALITY CONDITION JUDGMENT SOLVER BASED ON THREE-PORT NON-VOLATILE DEVICE AND OPERATION METHOD THEREOF

(71) Applicant: ZHEJIANG UNIVERSITY, ZHEJIANG (CN)

(72) Inventors: Xunzhao YIN, Zhejiang (CN); Yu Qian, Zhejiang (CN); Cheng ZHUO, Zhejiang (CN)

(73) Assignee: ZHEJIANG UNIVERSITY, ZHEJIANG (CN)

(21) Appl. No.: 18/762,586

(22) Filed: Jul. 2, 2024

(30) Foreign Application Priority Data
May 20, 2024 (CN) 202410623690.X

(51) Int. Cl. G06F 30/337; G06F 17/11

(52) U.S. Cl. CPC G06F 30/337; G06F 17/11

(57) ABSTRACT

The present invention discloses an inequality condition judgment solver based on a three-port non-volatile device and an operation method thereof, including two arrays and a voltage comparator, where the array includes m×n inequality units, a PMOS, and capacitance C_{ML}, the inequality units include a three-port non-volatile device, in the three-port non-volatile device, a gate is connected to an input signal G, a drain is connected to an ML, and a source is connected to ground, in the PMOS, a gate is connected to an input signal Vₚᵣₑ, a drain is connected to the ML, and a source is connected to a power supply, and the capacitance C_{ML} is connected to the ML and ground.

### CROSS-REFERENCE TO RELATED APPLICATION

This application claims the priority benefit of China application no. 202410623690.X, filed on May 20, 2024. The entirety of the above-mentioned patent application is hereby incorporated by reference herein and made a part of this specification.

### FIELD OF TECHNOLOGY

The present invention relates to the field of storage and inequality condition judgment, and in particular to a working principle and operation method of an inequality condition judgment solver based on a three-port non-volatile device.

### BACKGROUND

Combinatorial optimization problems are widely used in various fields such as logistics, resource allocation, communication network design, finance, drug discovery, and transportation systems. These problems typically belong to non-deterministic polynomial time hard problems (NP-hard), representing some of the most challenging computational tasks in the NP field.

It is difficult to solve combinatorial optimization problems using digital computers based on the von Neumann architecture, as the required resources grow exponentially in terms of computing power and latency as the problem size increases. Therefore, there is an urgent need to explore new hardware designs and adopt alternative architectures and algorithms to effectively solve combinatorial optimization problems.

At present, there are many solvers based on an Ising model and a QUBO model to solve these combinatorial optimization problems. However, the implementation of these solvers is mostly limited to handling simple unconstrained combinatorial optimization problems, and there is less research on combinatorial optimization problems with general inequality constraints, and there is a lack of processors for judging inequality partial conditions.

Based on the above issues, in order to reduce the resource cost of the solver, improve scalability, and increase the scope of solvable combinatorial optimization problems, the applicant proposes a working principle and operation method of an inequality condition judgment solver based on a three-port non-volatile device.

### SUMMARY

The purpose of the present invention is to provide an inequality condition judgment solver based on a three-port non-volatile device and an operation method thereof for solving problems where current solvers based on the Ising model and the QUBO model cannot directly handle inequality constraints and are limited to solving partial types of combinatorial optimization problems.

The purpose of the present invention is achieved through the following technical solutions:
an inequality condition judgment solver based on a three-port non-volatile device, including two arrays and a voltage comparator, where output signal lines of the two arrays are connected to two input terminals of the voltage comparator, and the two arrays are an array 1 and an array 2, the array includes m×n inequality units, a PMOS and capacitance C_{ML}, each inequality unit includes a three-port non-volatile device, in the three-port non-volatile device, a gate is connected to an input signal G, a drain is connected to an ML, and a source is connected to ground, the three-port non-volatile device in a same array share the signal line ML, the three-port non-volatile devices of a same column share an input line G, in the PMOS, a gate is connected to an input signal Vₚᵣₑ, a drain is connected to the ML, and a source is connected to a power supply, and the capacitance C_{ML} is connected to the ML and ground.

Furthermore, the three-port non-volatile device is an inequality unit composed of an FeFET or 1FeFET-1R or 1ReRAM-1T.

Furthermore, the voltage comparator is a two-stage comparator.

The present invention further provides an operation method of the inequality condition judgment solver as described above, including:
a preparation stage: before the array starts working, storing parameters of an inequality in the two arrays, and assuming that the inequality to be judged is \vec{w}\vec{x}≤C, where each element xᵢ of an input variable x can only be 0 or 1; and meanwhile, presetting an input variable \vec{x′} that satisfies \vec{w}\vec{x′}=C; and a working stage:
   a) precharging the capacitance C_{ML} on the ML through the PMOS, i.e. charging the ML of both the array 1 and array 2 to a power supply voltage VDD;
   b) according to the input variable x of the inequality, inputting to the array 1: if xᵢ=0, applying 0 V voltage to the signal line G in an i-th column, and if xᵢ=1, applying a stepped voltage, where a voltage value of each step is a corresponding voltage threshold that the three-port non-volatile device is capable of storing; when an applied voltage exceeds the voltage threshold of the three-port non-volatile device, turning on the three-port non-volatile device, causing the ML to discharge to ground, and conversely, turning off the three-port non-volatile device, keeping the voltage on the ML unchanged; meanwhile, according to the preset \vec{x} in the preparation stage, inputting to the array 2: if x′ᵢ=0, applying 0 V voltage to the signal line G in an i-th column, and if x′ᵢ=1, applying a stepped voltage, where a voltage value of each step is a corresponding voltage threshold that the three-port non-volatile device is capable of storing; when an applied voltage exceeds the voltage threshold of the three-port non-volatile device, turning on the three-port non-volatile device, causing the ML to discharge to ground, and conversely, turning off the three-port non-volatile device, keeping the voltage on the ML unchanged; and due to the short overall working time, being capable of approximately assuming that a discharge current is constant, and the voltage on the ML of the array 1 is negatively correlated with

$${\sum }_{i = 1}^{n} {w}_{i} {x}_{i} ( ML ∝ - \vec{w} \vec{x} ) ,$$

while the voltage on the ML of the array 2 is negatively correlated with

$${\sum }_{i = 1}^{n} {w}_{i} {x}_{i}^{′} ( ML ∝ - C ) ;$$

and
c) putting the ML of the two arrays into the voltage comparator for comparison to be capable of determining a relative size relationship of \vec{w}\vec{x} and C, and then judging whether the inequality is valid.

Furthermore, the preparation stage specifically includes: assuming the inequality is

$${\sum }_{i = 1}^{n} {w}_{i} {x}_{i} \leq C ,$$

first storing n parameters wᵢ in a three-port non-volatile device, and considering that the storage data range of a single three-port non-volatile device is limited, being capable of using multiple three-port non-volatile devices on a column to store a single parameter wᵢ, and using n columns to store n parameters wᵢ; and meanwhile, preparing a suitable input variable \vec{x′} that satisfies

$${\sum }_{i = 1}^{n} {w}_{i} {x}_{i}^{′} = C .$$

Compared with the prior art, the beneficial effects of the present invention are as follows:

The inequality condition judgment solver based on a three-port non-volatile device in the present invention can accelerate the inequality condition judgment process. This architecture makes full use of the characteristics of three ports, and by operating the other two ports except the grounding port, the state of the non-volatile device is controlled by two signals at the same time, and then satisfies the inequality operation.

### BRIEF DESCRIPTION OF THE DRAWINGS

FIG. 1 is a schematic and example diagram of an inequality unit of an inequality condition judgment solver based on a three-port non-volatile device; and

FIG. 2 is an overall schematic and example diagram of an inequality condition judgment solver based on a three-port non-volatile device.

### DESCRIPTION OF THE EMBODIMENTS

The following will provide a clear and complete description of technical solutions in embodiments of the present invention, in conjunction with the accompanying drawings in the embodiments of the present invention. Obviously, the described embodiments are only part of the embodiments, not all of the embodiments in the present invention. Based on the embodiments in the present invention, all other embodiments obtained by those of ordinary skill in the art without creative labor fall within the scope of protection of the present invention.

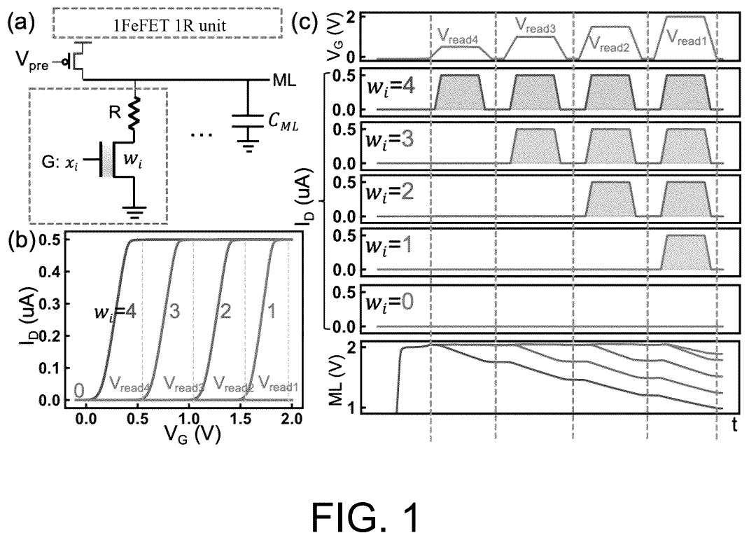

Please refer to FIG. 1. An inequality condition judgment solver based on a three-port non-volatile device includes two inequality arrays based on a non-volatile device constituting m rows×n columns and a voltage comparator. The inequality arrays include m×n inequality units, one PMOS and capacitance C_{ML}. Each inequality unit includes a three-port non-volatile device, in the three-port non-volatile device structure, a gate is connected to an input signal G, a drain is connected to an ML, and a source is connected to ground, the three-port non-volatile device in a same array share the signal line ML, the three-port non-volatile devices of a same column share an input line G; in the PMOS, a gate is connected to an input signal Vₚᵣₑ, a drain is connected to the ML, and a source is connected to a power supply; and the capacitance C_{ML} is connected to the ML and ground. The voltage comparator is a two-stage comparator.

Furthermore, the three-port non-volatile device is an inequality unit composed of an FeFET or 1FeFET-1R (as shown in (a) of FIG. 1) or 1ReRAM-1T.

The 1ReRAM-1T is a 1TIR unit in FIG. 1 of the following literature.

Xue C X, Chen W H, Liu J S, et al. 24.1 A 1 Mb multibit ReRAM computing-in-memory macro with 14.6 ns parallel MAC computing time for CNN based AI edge processors[C]//2019 IEEE International Solid-State Circuits Conference-(ISSCC). IEEE, 2019: 388-390.

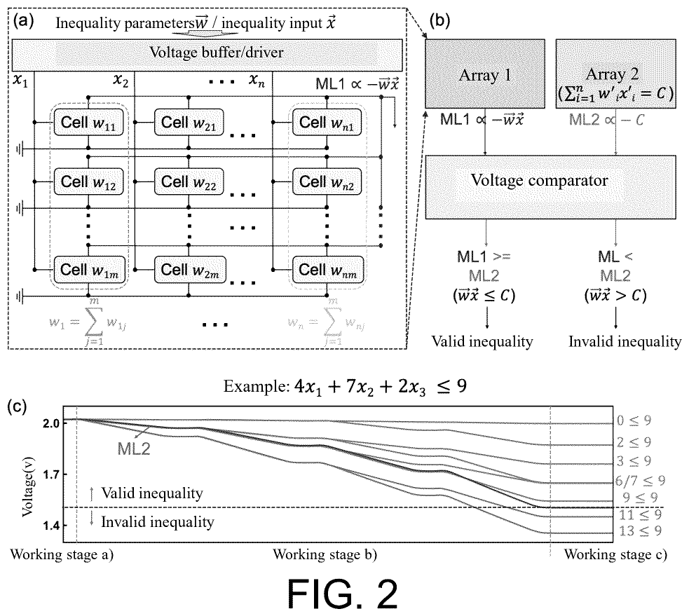

Please refer to FIGS. 1 and 2. An operation method of the inequality condition judgment solver as described above includes:
a preparation stage: before the array starts working, storing parameters of an inequality in the two arrays, and assuming that the inequality to be judged is \vec{w}\vec{x}≤C, where each element xᵢ of an input variable \vec{x} can only be 0 or 1; and the preparation stage specifically includes:
assuming the inequality is

$${\sum }_{i = 1}^{n} {w}_{i} {x}_{i} \leq C ,$$

first storing n parameters wᵢ in a three-port non-volatile device, and considering that the storage data range of a single three-port non-volatile device is limited, being capable of using multiple three-port non-volatile devices on a column to store a single parameter wᵢ, and using n columns to store n parameters wᵢ; and meanwhile, preparing a suitable input \vec{x′} that satisfies

$${\sum }_{i = 1}^{n} {w}_{i} {x}_{i}^{′} = C .$$

a working stage:
a) precharging the capacitance C_{ML} on the ML through the PMOS, i.e. charging the ML of both the array 1 and array 2 to a power supply voltage VDD;
b) according to the input variable x of the inequality, inputting to the array 1: if xᵢ=0, applying 0 V voltage to the signal line G in an i-th column, and if xᵢ=1, applying a stepped voltage, where a voltage value of each step is a corresponding voltage threshold that the three-port non-volatile device is capable of storing; when an applied voltage exceeds the voltage threshold of the three-port non-volatile device, turning on the three-port non-volatile device, causing the ML to discharge to ground, and conversely, turning off the three-port non-volatile device, keeping the voltage on the ML unchanged; meanwhile, according to the preset \vec{x′} in the preparation stage, inputting to the array 2: if x′ᵢ=0, applying 0 V voltage to the signal line G in an i-th column, and if x′ᵢ=1, applying a stepped voltage, where a voltage value of each step is a corresponding voltage threshold that the three-port non-volatile device is capable of storing; when an applied voltage exceeds the voltage threshold of the three-port non-volatile device, turning on the three-port non-volatile device, causing the ML to discharge to ground, and conversely, turning off the three-port non-volatile device, keeping the voltage on the ML unchanged; and due to the short overall working time, being capable of approximately assuming that a discharge current is constant, and the voltage on the ML of the array 1 is negatively correlated with

$${\sum }_{i = 1}^{n} {w}_{i} {x}_{i} ( ML ∝ - \vec{w} \vec{x} ) ,$$

while the voltage on the ML of the array 2 is negatively correlated with

$${\sum }_{i = 1}^{n} {w}_{i} {x}_{i}^{′} ( ML ∝ - C ) ;$$

and
c) putting the ML of the two arrays into the voltage comparator for comparison to be capable of determining a relative size relationship of \vec{w}\vec{x} and C, and then judging whether the inequality is valid.

### EMBODIMENT

As shown in (b) of FIG. 1, the inequality unit could store 5 different types of wᵢ (wᵢ=0,1,2,3,4). wᵢ=0 represented that the inequality unit could not be turned on, and wᵢ=1/2/3/4 corresponded to a voltage threshold of 2/1.5/1/0/5 V, respectively.

In the working stage, when xᵢ=0 was input, a gate input voltage V_{read} remained at 0 V; and when xᵢ=1 was input, a stepped voltage V_{read} containing four steps was input to the gate, and its size corresponded to a voltage threshold value of wᵢ=4/3/2/1, i.e., 0.5/1/1.5/2 V.

The (c) of FIG. 1 shows an input voltage, conduction current, and voltage of an ML of an inequality unit storing 5 different wᵢ when xᵢ=1 was input. As could be seen, when wᵢ=4/3/2/1/0, the occurrence number of conduction current was 4/3/2/1/0, and the corresponding number of voltage drops of the ML was 4/3/2/1/0. From the bottom figure of (c) of FIG. 1, it could be seen that voltage values of the final 5 ML were approximately in a linear relation that satisfied the condition of ML∝−wᵢxᵢ.

The (a) of FIG. 2 shows an overall framework of an array 1 in an inequality condition judgment solver, (b) of FIG. 2 shows an overall framework of an inequality condition judgment solver, and (c) of FIG. 2 shows all possible input and output results of an inequality condition judgment solver in solving example inequalities. The simulation results show that the proposed inequality condition judgment solver could successfully identify whether the inequality was valid or not and execute its function correctly.

Although the embodiments of the present invention have been shown and described, it can be understood by those of ordinary skill in the art that multiple variations, modifications, substitutions, and variations can be made to these embodiments without departing from the principles and spirit of the present invention, the scope of which is defined by the appended claims and their equivalents.

What is claimed is:

1. An inequality condition judgment solver based on a three-port non-volatile device, comprising two arrays and a voltage comparator, wherein output signal lines of the two arrays are connected to two input terminals of the voltage comparator, and the two arrays are a first array and a second array, the array comprises m×n inequality units, a PMOS and capacitance C_{ML}, each inequality unit comprises a three-port non-volatile device, in the three-port non-volatile device, a gate is connected to an input signal G, a drain is connected to a signal line (ML), and a source is connected to ground, the three-port non-volatile device in a same array share the signal line ML, the three-port non-volatile devices of a same column share an input line G, in the PMOS, a gate is connected to an input signal Vₚᵣₑ, a drain is connected to the ML, and a source is connected to a power supply, and the capacitance C_{ML} is connected to the ML and the ground.

2. The inequality condition judgment solver based on a three-port non-volatile device according to claim 1, wherein the three-port non-volatile device is an inequality unit composed of an FeFET or 1FeFET-1R or 1ReRAM-1T.

3. The inequality condition judgment solver based on a three-port non-volatile device according to claim 1, wherein the voltage comparator is a two-stage comparator.

4. An operation method of the inequality condition judgment solver according to claim 1, comprising:
a preparation stage: before the array starts working, storing parameters of an inequality in the two arrays, and assuming that the inequality to be judged is \vec{W}\vec{x}≤C, wherein each element xᵢ of an input variable \vec{x} can only be 0 or 1; and meanwhile, presetting an input variable \vec{x′} that satisfies \vec{W}\vec{x}′=C; and
a working stage:
a) precharging the capacitance C_{ML} on the ML through the PMOS, i.e. charging the ML of both the first array and second array to a power supply voltage VDD;
b) according to the input variable \vec{x} of the inequality, inputting to the first array: if xᵢ=0, applying 0 V voltage to the signal line G in an i-th column, and if xᵢ=1, applying a stepped voltage, wherein a voltage value of each step is a corresponding voltage threshold that the three-port non-volatile device is capable of storing; when an applied voltage exceeds the voltage threshold of the three-port non-volatile device, turning on the three-port non-volatile device, causing the ML to discharge to the ground, and conversely, turning off the three-port non-volatile device, keeping the voltage on the ML unchanged; meanwhile, according to the preset \vec{x′} in the preparation stage, inputting to the second array: if x′ᵢ=0, applying 0 V voltage to the signal line G in an i-th column, and if x′ᵢ=1, applying a stepped voltage, wherein a voltage value of each step is a corresponding voltage threshold that the three-port non-volatile device is capable of storing; when an applied voltage exceeds the voltage threshold of the three-port non-volatile device, turning on the three-port non-volatile device, causing the ML to discharge to ground, and conversely, turning off the three-port non-volatile device, keeping the voltage on the ML unchanged; and due to the short overall working time, being capable of approximately assuming that a discharge current is constant, and the voltage on the ML of the first array is negatively correlated with
$${\sum }_{i = 1}^{n} {w}_{i} {x}_{i} ( ML ∝ - \vec{w} \vec{x} ) ,$$
while the voltage on the ML of the second array is negatively correlated with
$${\sum }_{i = 1}^{n} {w}_{i} {x}_{i}^{′} ( ML ∝ - C ) ;$$
and
c) putting the ML of the two arrays into the voltage comparator for comparison to be capable of determining a relative size relationship of \vec{w}\vec{x} and C, and then judging whether the inequality is valid.

5. The operation method according to claim 4, wherein the preparation stage specifically comprises:
assuming the inequality is
$${\sum }_{i = 1}^{n} {w}_{i} {x}_{i} \leq C ,$$
first storing n parameters wᵢ in a three-port non-volatile device, and considering that the storage data range of a single three-port non-volatile device is limited, being capable of using multiple three-port non-volatile devices on a column to store a single parameter wᵢ, and using n columns to store n parameters wᵢ; and meanwhile, preparing a suitable input variable \vec{x′} that satisfies
$${\sum }_{i = 1}^{n} {w}_{i} {x}_{i}^{′} = C .$$
